(19) United States
(12) Patent Application Publication
(10) Pub. No.: US 2016/0343603 A1
(43) Pub. Date: Nov. 24, 2016

(54) WAFER TRANSPORT DEVICE

(71) Applicant: Episil Technologies Inc., Hsinchu City (TW)

(72) Inventor: Jain-Yuan Feng, Hsinchu City (TW)

(21) Appl. No.: 14/825,176

(22) Filed: Aug. 13, 2015

(30) Foreign Application Priority Data
May 20, 2015 (TW) 104207763

(51) Int. Cl. H01L 21/687; B25J 15/00; B25J 11/00

(52) U.S. Cl. CPC H01L 21/68735; B25J 11/0095; B25J 15/0014; H01L 21/68771; H01L 21/68785

(57) ABSTRACT

A wafer transport device including a robot arm and a C-ring is provided. The C-ring is disposed on the robot aim. The C-ring includes a C-ring body and a staircase structure. The staircase structure is disposed on an inner side of the C-ring body. The staircase structure has a plurality of wafer carrying surfaces, and heights of the wafer carrying surfaces are gradually decreases toward an interior of the C-ring.

### CROSS REFERENCE TO RELATED APPLICATION

This application claims the priority benefit of Taiwan application serial no. 104207763, filed on May 20, 2015. The entirety of the above-mentioned patent application is hereby incorporated by reference herein and made a part of specification.

### BACKGROUND OF THE INVENTION

Field of the Invention

The invention relates to a wafer transport device, and particularly relates to a wafer transport device using a robot arm.

Description of Related Art

Original wafer transport robot arm can only transport wafers of a single size, and if wafers of the other sizes are to be transported, the wafer transport robot arm has to be modified and corrected for transporting the wafers of the other sizes.

However, a process of modifying and correcting the wafer transport robot arm is time-consuming, and a correcting error may cause a transport error to result in wafer waste, such that a manufacturing cost is increased. Moreover, frequent modification of the wafer transport robot arm may cause loss and deformation of components therein, such that a maintenance cost of the wafer transport robot arm is increased.

### SUMMARY OF THE INVENTION

Accordingly, the invention is directed to a wafer transport device, which is capable of transporting wafers of different sizes without machine modification.

The invention provides a wafer transport device including a robot arm and a C-ring. The C-ring is disposed on the robot arm. The C-ring includes a C-ring body and a staircase structure. The staircase structure is disposed on an inner side of the C-ring body. The staircase structure has a plurality of wafer carrying surfaces, and heights of the wafer carrying surfaces are gradually decreases toward an interior of the C-ring.

In an embodiment of the invention, in the wafer transport device, the C-ring and the robot arm are formed integrally or are independent members, for instance.

In an embodiment of the invention, in the wafer transport device, the C-ring body may have a first inclined surface, wherein the first inclined surface is located between an upper surface of the C-ring body and the uppermost wafer carrying surface.

In an embodiment of the invention, in the wafer transport device, the first inclined surface is a non-90-degree inclined surface, a 90-degree inclined surface or a combination thereof, for instance.

In an embodiment of the invention, in the wafer transport device, the staircase structure and the C-ring body are formed integrally or are independent members, for instance.

In an embodiment of the invention, in the wafer transport device, the staircase structure includes a plurality of staircases separated from each other.

In an embodiment of the invention, in the wafer transport device, the staircase structure is a single C-ring staircase, for instance.

In an embodiment of the invention, in the wafer transport device, the staircase structure may have a second inclined surface between every two adjacent wafer carrying surfaces.

In an embodiment of the invention, in the wafer transport device, the second inclined surface is a non-90-degree inclined surface, a 90-degree inclined surface or a combination thereof, for instance.

In an embodiment of the invention, in the wafer transport device, sizes of wafers to be carried by the wafer carrying surfaces are gradually decreases toward the interior of the C-ring, for instance.

According to the above description, in the wafer transport device of the invention, since the staircase structure of the C-ring has a plurality of wafer carrying surfaces, and different wafer carrying surfaces are adapted to carry wafers of different sizes, the wafer of different sizes can be transported without performing machine modification, so as to improve a usage rate of the wafer transport device.

Moreover, since the wafer transport device provided by the invention is adapted to transport wafers of different sizes without performing machine modification, correction error caused by the machine modification is avoided, and high machine stability is achieved, such that wafer waste caused by transport error can be avoided to decrease a product manufacturing cost. On the other hand, loss and deformation of components in the wafer transport device of the invention caused by machine modification are avoided, such that a maintenance cost of the machine can be decreased.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional view of a wafer transport device according to a first embodiment of the invention.

FIG. 2 is a top view of the wafer transport device of FIG. 1.

FIG. 3A to FIG. 3C are cross-sectional views of a C-ring body of FIG. 2 along section lines I-I′ and II-II′.

FIG. 4A to FIG. 4C are cross-sectional views of staircases of FIG. 2 along section lines III-III′ and IV-IV′.

FIG. 5 is a three-dimensional view of a wafer transport device according to a second embodiment of the invention.

FIG. 6 is a top view of the wafer transport device of FIG. 5.

FIG. 7 is a three-dimensional view of a wafer transport device according to a third embodiment of the invention.

FIG. 8 is a top view of the wafer transport device of FIG. 7.

### DESCRIPTION OF EMBODIMENTS

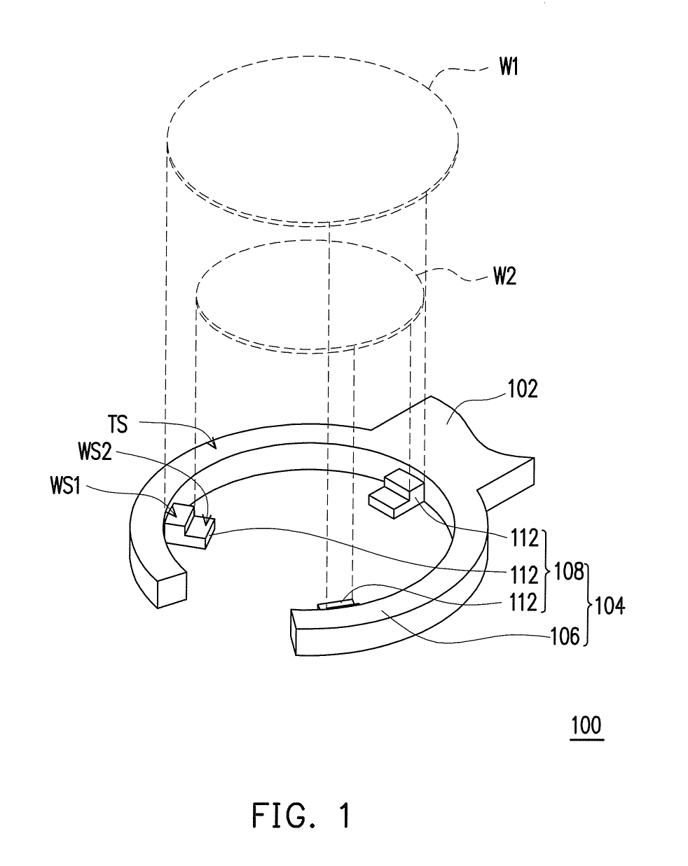

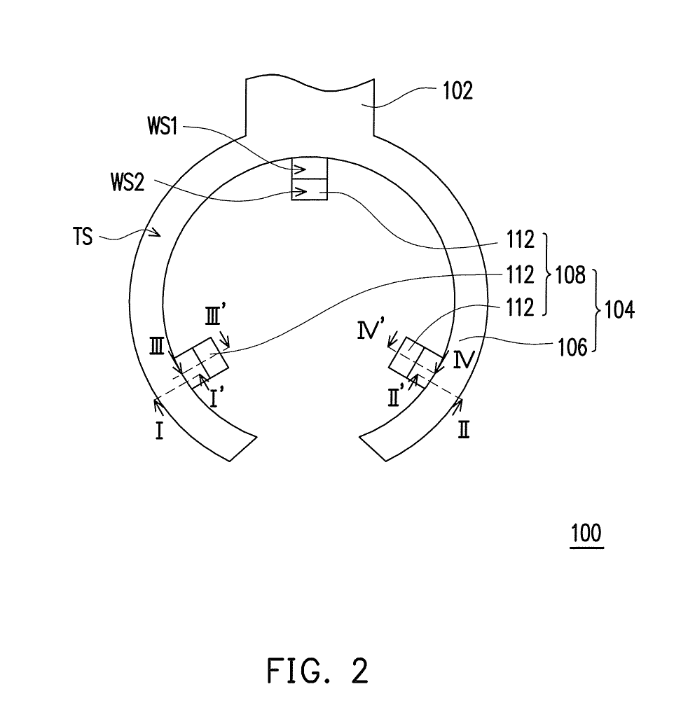

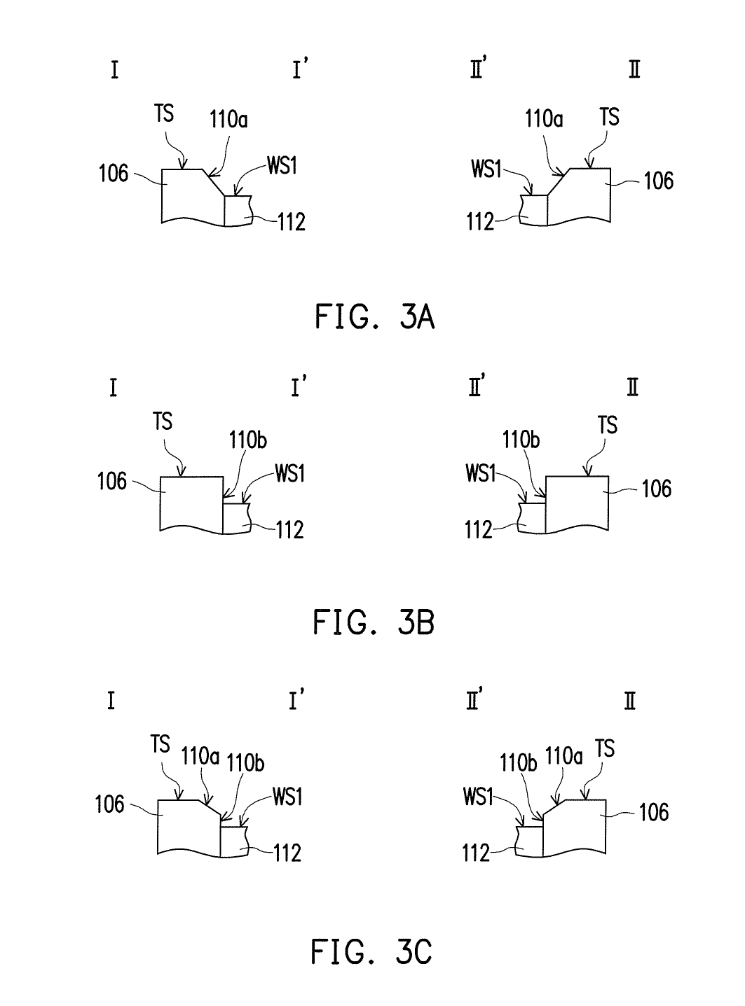

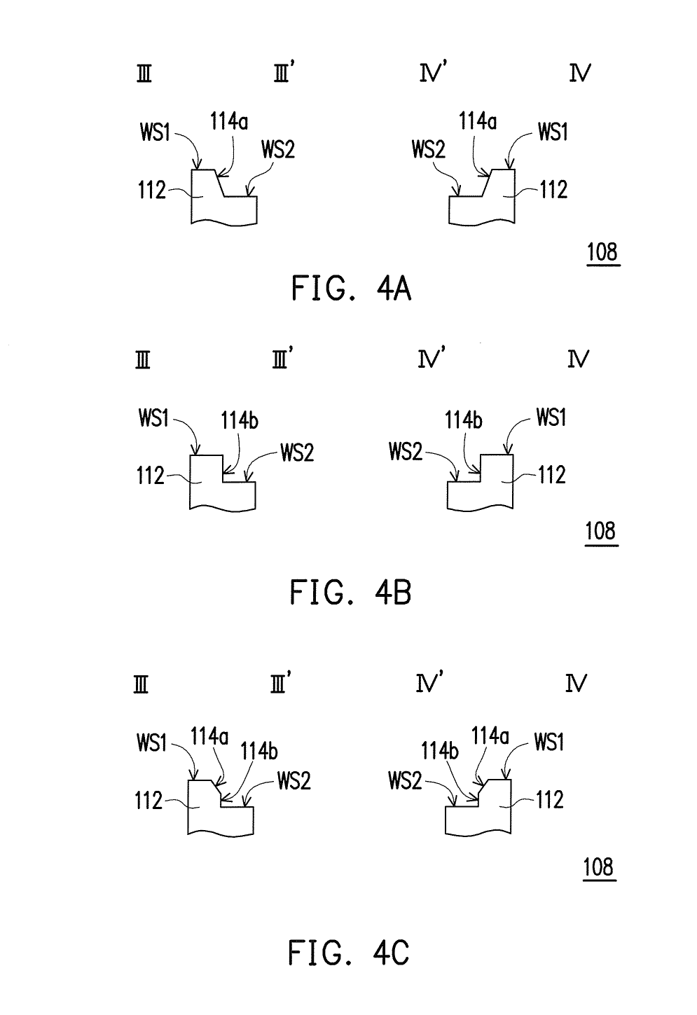

FIG. 1 is a three-dimensional view of a wafer transport device according to a first embodiment of the invention. FIG. 2 is a top view of the wafer transport device of FIG. 1. FIG. 3A to FIG. 3C are cross-sectional views of a C-ring body of FIG. 2 along section lines I-I′ and II-II′. FIG. 4A to FIG. 4C are cross-sectional views of staircases of FIG. 2 along section lines III-III′ and IV-IV′.

Referring to FIG. 1 and FIG. 2, the wafer transport device 100 includes a robot arm 102 and a C-ring 104. The wafer transport device 100 is adapted to transport wafers of different sizes in various semiconductor processes (for example, a photolithography process). A material of the robot arm 102 is, for example, Teflon, metal alloy, ceramic, or PVC, etc., that is not liable to be deformed.

The C-ring 104 is disposed on the robot arm 102. The C-ring 104 includes a C-ring body 106 and a staircase structure 108. The C-ring 104 and the robot arm 102 are formed integrally or are independent members, for example. A material of the C-ring is, for example, Teflon, metal alloy, ceramic, or PVC, etc., that is not liable to be deformed.

The staircase structure 108 is disposed on an inner side of the C-ring body 106. The staircase structure 108 has wafer carrying surfaces WS1 and WS2, and heights of the wafer carrying surfaces WS1 and WS2 are gradually decreases toward an interior of the C-ring 104. The wafer carrying surface WS1 can be adapted to carry a wafer W1, and the wafer carrying surface WS2 can be adapted to carry a wafer W2. Sizes of the wafers W1 and W2 to be carried by the wafer carrying surfaces WS1 and WS2 are, for example, gradually decreases toward the interior of the C-ring. The staircase structure 108 and the C-ring body 106 are formed integrally or are independent members, for example.

Referring to FIG. 3A to FIG. 3C, the C-ring body 106 may have an inclined surface 110a and/or an inclined surface 110b, for example, the non-90-degree inclined surface 110a in FIG. 3A, the 90-degree inclined surface 110b in FIG. 3B, or a combination of the non-90-degree inclined surface 110a and the 90-degree inclined surface 110b in FIG. 3C, wherein the inclined surface 110a and/or the inclined surface 110b is located between an upper surface TS of the C-ring body 106 and the uppermost wafer carrying surface WS1. When the C-ring body 106 has the non-90-degree inclined surface 110a, it avails placing the wafer W1 on the wafer carrying surface WS1. Moreover, based on a section difference of the C-ring body 106, the wafer W1 can be stably kept on the wafer carrying surface WS1 even when the robot arm 102 moves.

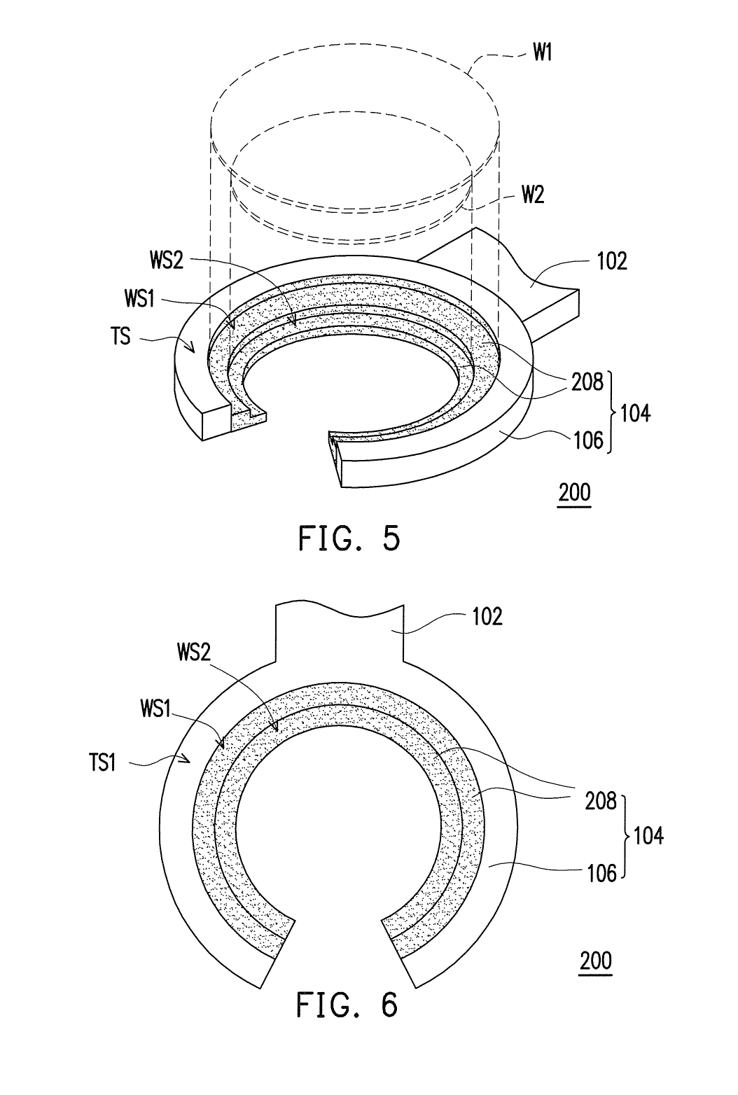

Referring to FIG. 1 and FIG. 2, the staircase structure 108 includes a plurality of staircases 112 separated from each other. In the present embodiment, an implementation that the staircase structure 108 has three staircases separated from each other is taken as an example for description, though the invention is not limited thereto, and the spirit of the invention is met as long as the pattern and the number of the designed staircases 112 can be adapted to stably carry the wafers W1 and W2, and those skilled in the art can adjust the pattern and the number of the staircases 112 according to an actual design requirement. For example, in another embodiment, the staircase structure 108 can be a single C-ring staircase (referring to FIG. 5 and FIG. 6).

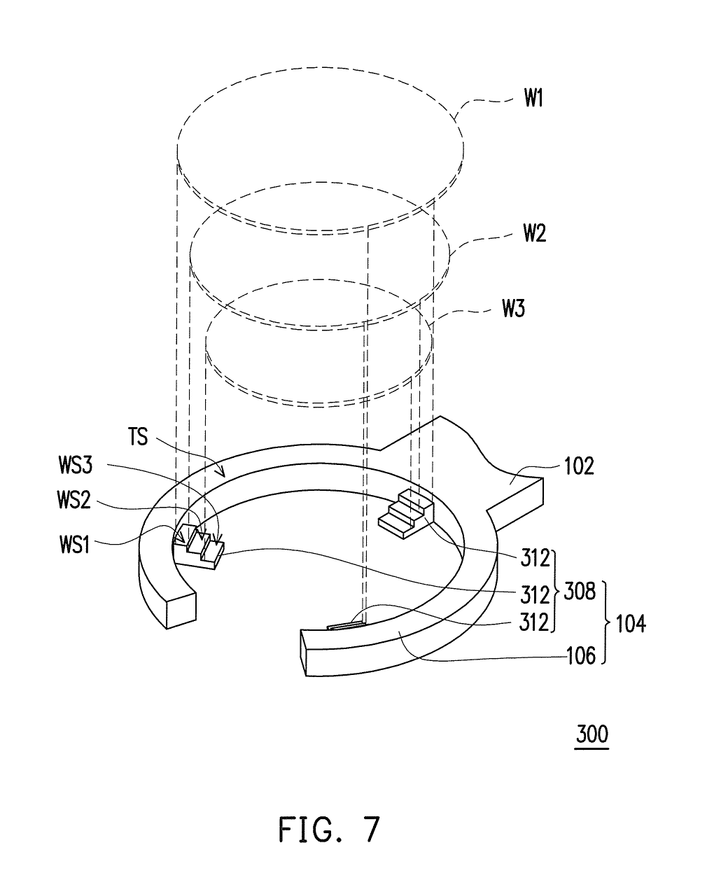

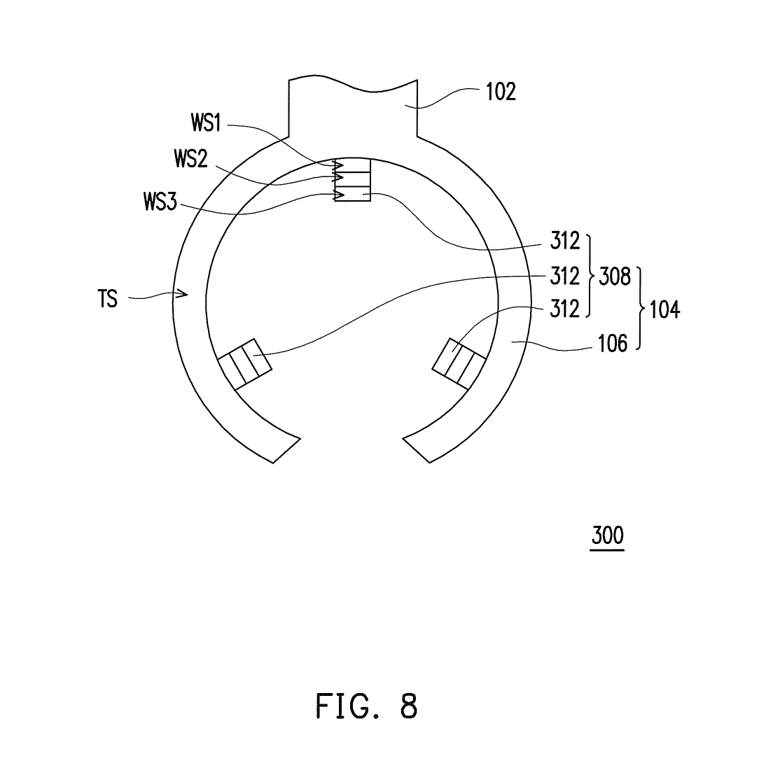

Moreover, an implementation that the staircase 112 has two steps to form the wafer carrying surfaces WS1 and WS2 is taken as an example for description, though the invention is not limited thereto. Those skilled in the art can design the staircase 112 to have three or more steps according to an actual design requirement, so as to form three or more carrying surfaces for carrying the wafers with three or more different sizes (referring to FIG. 7 and FIG. 8).

Referring to FIG. 4A to FIG. 4C, the staircase 112 in the staircase structure 108 may have an inclined surface 114a and/or an inclined surface 114b between two adjacent wafer carrying surfaces WS1 and WS2, for example, the non-90-degree inclined surface 114a in FIG. 4A, the 90-degree inclined surface 114b in FIG. 4B, or a combination of the non-90-degree inclined surface 114a and the 90-degree inclined surface 114b in FIG. 4C. When the staircase structure 108 has the non-90-degree inclined surface 114a, it avails placing the wafer W2 on the wafer carrying surface WS2. Moreover, based on a section difference of the staircase structure 108, the wafer W2 can be stably kept on the wafer carrying surface WS2 even when the robot arm 102 moves.

According to aforementioned embodiment, it is known that in the wafer transport device 100, since the staircase structure 108 of the C-ring 104 has the wafer carrying surfaces WS1 and WS2, and the wafer carrying surfaces WS1 and WS2 can be respectively used for carrying the wafers W1 and W2 with different sizes, the wafers W1 and W2 with different sizes can be transported without machine modification, so as to improve a usage rate of the machine.

Moreover, since the wafer transport device 100 can transport the wafers W1 and W2 with different sizes without machine modification, correction error caused by the machine modification is avoided, and high machine stability is achieved, such that wafer waste caused by transport error can be avoided to decrease a product manufacturing cost. On the other hand, loss and deformation of components in the wafer transport device 100 caused by machine modification are avoided, such that a maintenance cost of the machine can be decreased.

FIG. 5 is a three-dimensional view of a wafer transport device according to a second embodiment of the invention. FIG. 6 is a top view of the wafer transport device of FIG. 5.

Referring to FIG. 1, FIG. 2, FIG. 5 and FIG. 6, a difference between the wafer transport device 200 of the second embodiment and the wafer transport device 100 of the first embodiment is that the staircase structure 208 in the wafer transport device 200 is a single C-ring staircase. Besides, the similar components in the wafer transport device 200 of the second embodiment and the wafer transport device 100 of the first embodiment have similar configurations, materials, characteristics and effects, which are denoted by the same referential numbers, so that details thereof are omitted.

FIG. 7 is a three-dimensional view of a wafer transport device according to a third embodiment of the invention. FIG. 8 is a top view of the wafer transport device of FIG. 7.

Referring to FIG. 1, FIG. 2, FIG. 7 and FIG. 8, a difference between the wafer transport device 300 of the third embodiment and the wafer transport device 100 of the first embodiment is that the staircases 312 in the staircase structure 308 of the wafer transport device 300 respectively have three steps to form the wafer carrying surfaces WS1, WS2 and WS3 respectively used for carrying the wafers W1, W2 and W3. In the present embodiment, an implementation that the staircase structure 308 has three staircases 312 separated from each other is taken as an example for description, though the invention is not limited thereto. In another embodiment, the staircase structure 308 can also be a single C-ring staircase. Besides, the similar components in the wafer transport device 300 of the third embodiment and the wafer transport device 100 of the first embodiment have similar configurations, materials, characteristics and effects, which are denoted by the same referential numbers, so that details thereof are omitted.

In summary, the aforementioned embodiments have at least following features. In the wafer transport device of the aforementioned embodiments, since the different wafer carrying surfaces of the staircase structure of the C-ring can carry wafers of different sizes, wafers of different sizes can be transported without performing machine modification. In this way, the usage rate of the machine can be improved, and maintenance cost of the machine and product manufacturing cost can be decreased.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A wafer transport device, comprising:
a robot arm; and
a C-ring, disposed on the robot arm, and comprising:
a C-ring body; and
a staircase structure, disposed on an inner side of the C-ring body, wherein the staircase structure has a plurality of wafer carrying surfaces, and heights of the wafer carrying surfaces are gradually decreases toward an interior of the C-ring.

2. The wafer transport device as claimed in claim 1, wherein the C-ring and the robot arm are formed integrally or are independent members.

3. The wafer transport device as claimed in claim 1, wherein the C-ring body has a first inclined surface, wherein the first inclined surface is located between an upper surface of the C-ring body and the uppermost wafer carrying surface.

4. The wafer transport device as claimed in claim 3, wherein the first inclined surface comprises a non-90-degree inclined surface, a 90-degree inclined surface or a combination thereof.

5. The wafer transport device as claimed in claim 1, wherein the staircase structure and the C-ring body are formed integrally or are independent members.

6. The wafer transport device as claimed in claim 1, wherein the staircase structure comprises a plurality of staircases separated from each other.

7. The wafer transport device as claimed in claim 1, wherein the staircase structure comprises a single C-ring staircase.

8. The wafer transport device as claimed in claim 1, wherein the staircase structure has a second inclined surface between every two adjacent wafer carrying surfaces.

9. The wafer transport device as claimed in claim 8, wherein the second inclined surface comprises a non-90-degree inclined surface, a 90-degree inclined surface or a combination thereof.

10. The wafer transport device as claimed in claim 1, wherein sizes of wafers to be carried by the wafer carrying surfaces are gradually decreases toward the interior of the C-ring.
